(19) United States
(12) Patent Application Publication
(10) Pub. No.: US 2008/0206995 A1
(43) Pub. Date: Aug. 28, 2008

(54) METAL-POLISHING LIQUID AND POLISHING METHOD THEREWITH

(75) Inventors: Takamitsu TOMIGA, Shizuoka-ken (JP); Tomoo KATO, Shizuoka-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 12/018,456

(22) Filed: Jan. 23, 2008

(30) Foreign Application Priority Data
Jan. 23, 2007 (JP) 2007-012665

(51) Int. Cl. H01L 21/302; C09K 13/00

(52) U.S. Cl. 438/693; 252/79.1; 257/E21.214

(57) ABSTRACT

The present invention provides a metal-polishing liquid that is used in chemical mechanical polishing for a conductor film made of copper or a copper alloy during semiconductor device production, wherein the metal-polishing liquid comprises the following components (1), (2) and (3):
(1) an amino-acid derivative represented by the following formula (I)

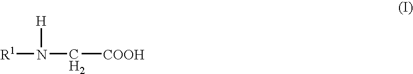

wherein in the formula (I), R¹ represents an alkyl group having 1 to 4 carbon atoms;
(2) colloidal silica in which silicon atoms on a surface thereof are at least partially modified by aluminum atoms; and (3) an oxidant.

### CROSS-REFERENCE TO RELATED APPLICATION

This application claims priority under 35 USC 119 from Japanese Patent Application No. 2007-012665, the disclosure of which is incorporated by reference herein.

### BACKGROUND

1. Technical Field

The present invention relates to a metal-polishing liquid and a polishing process therewith, in more detail, a metal-polishing liquid used in a wiring process in semiconductor device production and a polishing process therewith.

2. Related Art

Recently, in the development of semiconductor devices typified by semiconductor integrated circuits (hereinafter, appropriately referred to as “LSI”), in order to achieve smaller size and higher speed, higher densification and higher integration by miniaturization of wirings and lamination are in demand. As a technique for this, various techniques such as chemical mechanical polishing (hereinafter, appropriately referred to as “CMP”) are in use. The CMP is a process that is used to polish metal thin films used in insulating thin films (SiO₂) and wirings in the production of semiconductor devices to remove superfluous metal thin films when a substrate is smoothed and wirings are formed (see, for instance, U.S. Pat. No. 4,944,836).

The metal-polishing liquid used in the CMP generally includes abrasive grains (such as alumina) and an oxidant (such as hydrogen peroxide). The mechanism of the polishing by means of the CMP is considered to be that the oxidant oxidizes a metal surface and a film of the oxide is removed by the abrasive grains to carry out polishing (see, for instance, Journal of Electrochemical Society, Vol. 138(11), pages 3460 to 3464 (1991)).

However, when the CMP is applied by use of the metal-polishing liquid containing such solid abrasive grains, in some cases, polishing scratches, a phenomenon where an entire polishing surface is polished more than necessary (thinning), a phenomenon where a polished metal surface is not planar, that is, only a center portion is polished deeper to form a dish-like concave (dishing), or a phenomenon where an insulating material between metal wirings is polished more than necessary and a plurality of wiring metal surfaces forms dish-like concaves (erosion) may be caused. Furthermore, when the metal-polishing liquid containing solid abrasive grains is used, in a cleaning process that is usually applied to remove the polishing liquid remaining on a polished semiconductor surface, the cleaning process becomes complicated and, furthermore, in order to dispose of the liquid after the washing (waste liquid), the solid abrasive grains have to be sedimented and separated; accordingly, there is a problem from the viewpoint of cost.

In order to overcome such problems of the conventional abrasive grains, for instance, a metal surface polishing process where a polishing liquid that does not contain abrasive grains and dry etching are combined is disclosed (see, for instance, Journal of Electrochemical Society, Vol. 147 (10), pages 3907 to 3913 (2000)). Furthermore, as a metal-polishing liquid that does not contain abrasive grains, a metal-polishing liquid that is made of hydrogen peroxide/malic acid/benzotriazole/ammonium polyacrylate and water, and a polishing process therewith are disclosed (see, for instance, Japanese Patent Application Laid-Open (JP-A) No. 2001-127019). According to the polishing processes described in these documents, a metal film of a convex portion of a semiconductor substrate is selectively subjected to the CMP and a metal film of a concave portion is left to form a desired conductor pattern. However, since the CMP advances due to friction with a polishing pad that is mechanically far softer than a conventional one that contains abrasive grains, there is a problem in that a sufficient polishing speed is difficult to obtain.

As wiring metals, so far, tungsten and aluminum have been generally used in the interconnect structure. However, in order to achieve higher performance, LSIs that use copper which is lower in wiring resistance than these metals have been developed. As a process for wiring copper, for instance, a damascene process disclosed in JP-A No. 2-278822 is known. Furthermore, a dual damascene process where a contact hole and a wiring groove are simultaneously formed in an interlayer insulating film and a metal is buried in both is in wide use. As a target material for such copper wiring, a copper target having high purity of five ninths or more has been used. However, recently, as the wirings are miniaturized to carry out further densification, the conductivity and electric characteristics of the copper wiring require improvement; accordingly, a copper alloy where a third component is added to high-purity copper is under study. Simultaneously, a high-performance metal-polishing means that can exert high productivity without contaminating the high-precision and high-purity material is in demand.

Furthermore, recently, in order to improve the productivity, a wafer diameter when LSIs are produced is enlarged. At present, a diameter of 200 mm or more is generally used, and production at a magnitude of 300 mm or more as well has been started. As the wafer diameter is made larger like this, a difference in polishing speeds at a center portion and a periphery portion of the wafer tends to occur; accordingly, achievement of uniformity in the polishing is becoming important.

As a chemical polishing process that does not apply mechanical polishing means to copper and a copper alloy, a process that makes use of a chemical solvent action is known (see, for instance, JP-A No. 49-122432). However, in the chemical polishing process that depends only on the chemical solvent action, in comparison with the CMP where a metal film of a convex portion is selectively chemomechanically polished, a concave portion is polished, that is, dishing is caused; accordingly, a large problem remains with respect to the planarity.

Furthermore, an aqueous dispersion element for chemical mechanical polishing, which contains an organic compound that inhibits the polishing pad from deteriorating, is disclosed (see, for instance, JP-A No. 2001-279231). However, even when the polishing aqueous dispersion element is used, there remains a concern in that the dishing phenomenon where a metal of a wiring portion is excessively polished to hollow out like a dish may be caused.

Other than the above, in order to planarize a polished surface, a working liquid that contains a chelating agent selected from iminodiacetate useful for correcting a wafer surface and salts thereof (see, for instance, Japanese Patent Application National Phase Publication No. 2002-538284) and a chemical mechanical polishing composition containing α-amino acid (see, for instance, JP-A No. 2003-507894) are proposed. Owing to these technologies, the polishing performance in the copper wiring may be improved.

Furthermore, usually, after the copper wiring is subjected to high-performance polishing, tantalum or a tantalum alloy that is frequently used as a barrier metal of the copper wiring and copper are precisely polished to planarize the vicinity of the wiring. Accordingly, realization of a polishing liquid that has, at the end of the copper polishing, polishing selectivity between copper and tantalum (hereinafter, appropriately referred to as “copper/tantalum polishing selectivity”) in which copper is readily ground and tantalum is difficult to grind is desired.

### SUMMARY

The present inventions have been made in view of the above circumstances and provide a metal-polishing liquid and a polishing process therewith.

A first aspect of the invention provides a metal-polishing liquid that is used in chemical mechanical polishing for a conductor film made of copper or a copper alloy during semiconductor device production, wherein the metal-polishing liquid comprises the following components (1), (2) and (3):
(1) an amino-acid derivative represented by the following formula (I)

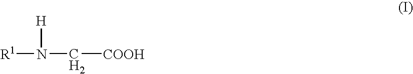

wherein in the formula (I), R¹ represents an alkyl group having 1 to 4 carbon atoms;
(2) colloidal silica in which silicon atoms on a surface thereof are at least partially modified by aluminum atoms; and (3) an oxidant.

A second aspect of the invention provides a polishing method comprising chemical mechanical polishing a substrate having a conductor film made of copper or a copper alloy with a metal-polishing liquid that contains the following components (1), (2) and (3) during semiconductor device production:
(1) a compound represented by the following formula (I)

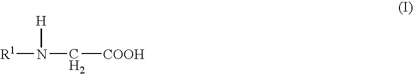

wherein in the formula (I), R¹ represents an alkyl group having 1 to 4 carbon atoms;
(2) colloidal silica in which silicon atoms on a surface thereof are at least partially modified by aluminum atoms; and (3) an oxidant.

### DETAILED DESCRIPTION

After intensive studies under the circumstances above, the inventors have found that it was possible to solve the problems above by using a metal-polishing liquid described below and a polishing method therewith, and completed the invention.

Hereinafter, specific embodiments of the invention will be described.

[Metal-polishing Liquid]

A metal-polishing liquid of the invention is a metal-polishing liquid that is used in chemical mechanical polishing for a conductor film made of copper or a copper alloy during semiconductor device production, wherein the metal-polishing liquid comprises the following components (1), (2) and (3):
(1) an amino-acid derivative represented by the following formula (I)

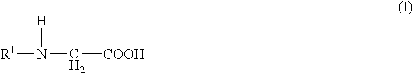

In the formula (I), R¹ represents an alkyl group having 1 to 4 carbon atoms.

(2) Colloidal silica in which silicon atoms on the surface thereof are at least partially modified by aluminum atoms, and (3) an oxidant.

Hereinafter, a metal-polishing liquid of the invention is described. However, the invention is not limited thereto.

A metal-polishing liquid of the invention is constituted by containing the components (1), (2) and (3) as essential components and, usually containing water. The metal-polishing liquid of the invention may, as needed, further contain other components. As preferable other components, additives such as a compound that is added as a so-called passivation film forming agent (such as an aromatic heterocyclic compound), a surfactant and/or hydrophilic polymer, an acid, an alkali and a buffering agent may be cited. The respective components (essential components and optional components) that the metal-polishing liquid contains may be used alone or in combination of at least two kinds thereof.

In the invention, the “metal-polishing liquid” includes not only a polishing liquid used in the polishing (namely, a polishing liquid diluted as needed) but also a concentrated liquid of the metal-polishing liquid.

The concentrated liquid of the metal-polishing liquid means a liquid that is prepared higher in a concentration of a solute than a polishing liquid when used in the polishing and is used in the polishing after dilution with water or an aqueous solution. The dilution factor is generally in the range of 1 to 20 times by volume.

In the specification of the invention, the term “concentration” and “concentrated liquid” are used in accordance with follow conventional expressions that mean a higher “concentration” and a more “concentrated liquid” compared with a usage state and are used in a manner that differs in meaning from a general terminology that accompanies a physical concentrate operation such as vaporization.

Hereinafter, the respective constituents contained in a metal-polishing liquid of the invention will be described. First, the respective components (1), (2) and (3) that are essential components in the metal-polishing liquid of the invention will be sequentially described.

<(1) Amino-Acid Derivate Represented by Formula (I)>

The metal-polishing liquid of the invention contains an amino-acid derivative represented by a formula (I) below (hereinafter, appropriately referred to as “particular amino-acid derivative”).

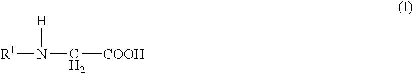

In the formula (I), R¹ represents an alkyl group having 1 to 4 carbon atoms.

R¹ represents an alkyl group having 1 to 4 carbon atoms and specific examples thereof include methyl group, ethyl group, n-propyl group, i-propyl group, n-butyl group, s-butyl group, i-butyl group and t-butyl group. Among these, methyl group, ethyl group, n-propyl group and n-butyl group are preferred. Methyl group, ethyl group and n-propyl group are more preferable and methyl group and ethyl group are still more preferable.

A methylene group in the formula (I) may further have a substituent group and examples of the substituent groups include carboxyl group, hydroxyl group, sulfo group and alkoxy group.

Hereinafter, specific examples of the particular amino acid derivatives (exemplified compounds A-1 through A-4) are shown. However, the invention is not limited thereto.

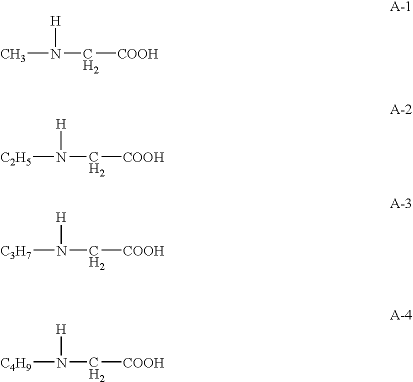

The particular amino acid derivative in the invention is preferably at least one kind selected from N-methylglycine and N-ethylglycine, from the viewpoint of a balance between the polishing speed and the dishing.

A content of the particular amino-acid derivative in the metal-polishing liquid of the invention is preferably in the range of from 0.01 to 10% by mass and more preferably in the range of from 0.05 to 5% by mass as a total amount, in the metal-polishing liquid when used in the polishing (Namely, in the case of using the metal-polishing liquid by diluting it with water or an aqueous solution, this refers to the diluted polishing liquid. Hereinafter, the “a polishing liquid when used in the polishing” has the same meaning.).

<(2) Colloidal Silica in Which at Least Part of Silicon Atoms on the Surface Thereof are Modified with Aluminum Atoms>

Colloidal silica in which at least part of silicon atoms on the surface thereof are modified with aluminum atoms (hereinafter, appropriately referred to as “particular colloidal silica”) serves as abrasive grains in the metal-polishing liquid of the invention.

In the invention, the “colloidal silica in which at least part of silicon atoms on the surface thereof are modified with aluminum atoms” means a state where on the surface of the colloidal silica having sites including silicon atoms having a coordination number of 4, aluminum atoms are present. This may be a state where, on a surface of the colloidal silica, aluminum atoms to which four oxygen atoms are coordinated are bonded and aluminum atoms are fixed in a state of four coordination to form a new surface, or a state where silicon atoms present on the surface are once drawn off and substituted by aluminum atoms to form a new surface.

The colloidal silica used in the preparation of the particular colloidal silica is more preferably colloidal silica that does not have impurities such as alkali metals inside of a particle and is obtained through hydrolysis of alkoxysilane. On the other hand, while colloidal silica that is produced according to a process where alkali is removed from an aqueous solution of alkali silicate can be used as well, in this case, there is a concern that alkali metal remaining inside of a particle is gradually eluted to adversely affect the polishing performance; accordingly, from such a viewpoint, one obtained through the hydrolysis of alkoxysilane is more preferred as a raw material. A particle diameter of colloidal silica that is to be a raw material, though appropriately selected in accordance with usage of the abrasive grains, is generally in the range of approximately from 10 to 200 nm.

As a method of modifying silicon atoms on a surface of such a colloidal silica particle with aluminum atoms to obtain the particular colloidal silica, for instance, a method where an aluminate compound such as ammonium aluminate is added to a dispersion solution of colloidal silica may be preferably used. More specifically, a method where an aluminum compound-containing alkaline silica sol prepared by a method where silica sol obtained by adding an aqueous solution of alkali aluminate is heated at a temperature in the range of 80 to 250° C. for 0.5 to 20 hr, followed by bringing it into contact with a cation exchange resin or a cation exchange resin and an anion exchange resin, a method where an acidic silicate solution and an aqueous solution of an aluminum compound are added to a SiO₂-containig alkali aqueous solution or an aqueous solution of alkali metal hydroxide, or a method where an acidic silicate solution in which an aluminum compound is mixed is added to a SiO₂-containing alkali aqueous solution or an aqueous solution of alkali metal hydroxide, is treated with a cation exchange resin to carry out dealkalization may be used. These methods are detailed in Japanese Patent No. 3463328 and JP-A No. 63-123807, and the descriptions thereof can be applied to the invention.

Furthermore, as other method, a method in which aluminum alkoxide is added to a dispersion solution of colloidal silica may be cited. Although whatever kinds of aluminum alkoxides may be used here, aluminum isopropoxide, aluminum butoxide, aluminum methoxide and aluminum ethoxide are preferable and aluminum isopropoxide and aluminum butoxide are more preferable.

The particular colloidal silica is excellent in the dispersibility even in an acidic state, because aluminosilicate sites generated via a reaction between four-coordinated aluminate ions and silanol groups on the surface of colloidal silica fix negative charges to impart a large negative zeta potential to the particle. Accordingly, it is important that the particular colloidal silica produced according to the aforementioned method is in the state that aluminum atoms are coordinated with four oxygen atoms.

It can be readily confirmed the structure that modification of silicon atoms and aluminum atoms is generated on the surface of colloidal silica by, for instance, measuring the zeta potential of abrasive grains.

A modification amount to aluminum atoms when silicon atoms on the surface of the colloidal silica are modified to aluminum atoms can be appropriately controlled by controlling an addition amount (concentration) of an aluminate compound or aluminum alkoxide added to a dispersion solution of colloidal silica.

An introduction amount of aluminum atoms to a surface of colloidal silica (number of introduced aluminum atoms/number of the sites of the surface silicon atoms) can be estimated by calculating the amount of consumed aluminum compound by subtracting the amount of unreacted aluminum compound remaining after reaction from the aluminum compound added to the dispersion solution, and assuming that the consumed aluminum compound reacted at a rate of 100%, based on the surface area calculated from a diameter of the colloidal silica, the specific gravity of the colloidal silica of 2.2, and number of silanol groups per unit surface area (5 to 8 groups/nm²). In an actual measurement, the obtained particular colloidal silica per se is subjected to elemental analysis, and, under the assumption that aluminum, without existing inside of a particle, spreads thinly and uniformly over a surface, the surface area of the colloidal silica/specific gravity and the number of silanol groups per unit area are used to obtain the introduction amount.

A specific example of a producing method of the particular colloidal silica will be cited. First, a dispersion solution in which colloidal silica is dispersed in water in the range of 5 to 25% by mass is prepared. A pH adjuster is added to the dispersion solution to adjust the pH in the range of 5 to 11, followed by slowly adding 15.9 g of sodium aluminate aqueous solution having an Al₂O₃ concentration of 3.6% by mass and a Na₂O/Al₂O₃ molar ratio of 1.50 under agitation over several minutes, further followed by further agitating for 0.5 hr. Thereafter, a solvent is removed to obtain the particular colloidal silica.

A primary particle diameter of the particular colloidal silica is preferably in the range of 5 to 100 nm and more preferably in the range of 20 to 60 nm. That is, primary particles of the particular colloidal silica are, from the viewpoint of inhibiting pad holes from clogging or the polishing speed from deteriorating due to the smallness of the particle diameter, preferred to be particles having a particle diameter of 20 nm or more and, from the viewpoint of inhibiting polishing faults and defects such as scratches from generating, preferred to be particles having a particle diameter of 60 nm or less.

Here, the primary particle diameter of the particular colloidal silica particles in the invention means, when a particle size cumulative curve that shows the relationship between particle diameters of the colloidal silica and the cumulative frequencies obtained by integrating the number of particles having the particle diameters is obtained, a particle diameter at a point where the cumulative frequency is 50% in the particle diameter cumulative curve.

The particle diameter of the colloidal silica particles represents an average particle diameter obtained from a particle size distribution curve obtained by use of a dynamic light scattering method. For instance, as a measurement unit for obtaining a particle size distribution curve, LB-500 (trade name, produced by Horiba Limited) may be used.

In the particular colloidal silica, from the viewpoint of inhibiting the polishing faults and defects from occurring, the degree of association of the particular colloidal silica is preferably 5 or less and more preferably 3 or less.

Here, the degree of association means a value obtained by dividing a diameter of a secondary particle formed through aggregation of primary particles by a diameter of a primary particle (diameter of secondary particle/diameter of primary diameter). The degree of association being 1 means the colloidal silica being made of only mono-dispersed primary particles.

As mentioned above, particular colloidal silica particles may be partially associated. Among the particular colloidal silica particles, associated secondary particles are, from the viewpoint of inhibiting the erosion and scratch from occurring, preferably 300 nm or less in the particle diameter. On the other hand, from the viewpoint of achieving a sufficient polishing speed, a lower limit value thereof is preferably 20 nm or more. Furthermore, secondary diameters of the particular colloidal silica particles are more preferably in the range of 20 to 200 nm.

The secondary particle diameter may be measured by use of an electron microscope.

Among the abrasive grains contained in the metal-polishing liquid of the invention, a mass ratio of the particular colloidal silica is preferably 50% or more and particularly preferably 80% or more. All of the contained abrasive grains may be the particular colloidal silica.

A content of the particular colloidal silica in the metal-polishing liquid of the invention is, from the viewpoint of diminishing the polishing faults and defects such as scratches, preferably 1% by mass or less, more preferably from 0.0001% by mass to 0.9% by mass, and still more preferably from 0.001% by mass to 0.7% by mass with respect to the metal-polishing liquid at the point of use in the polishing.

The metal-polishing liquid of the invention may contain, in addition to the particular colloidal silica, other abrasive grains other than the particular colloidal silica in a range that does not impair the effects of the invention. Examples of the usable abrasive grains which may be used include fumed silica, colloidal silica, ceria, alumina and titania, and the colloidal silica is particularly preferred.

Sizes of the abrasive grains other than the particular colloidal silica are preferably equal to or greater than that of the particular colloidal silica but no more than twice the size of the particular colloidal silica.

<(3) Oxidant>

The polishing composition according to the invention contains an oxidizing agent (compound that oxidize the metal favorably to be polished).

Examples of the oxidizing agents include hydrogen peroxide, peroxides, nitrate salts, iodate salts, periodate salts, hypochlorite salts, chlorite salts, chlorate salts, perchlorate salts, persulfate acid salts, dichromate salts, permanganate salts, ozone water, silver (II) salts, and iron (III) salts.

Favorable examples of the iron (III) salts include inorganic iron (III) salts such as iron nitrate (III), iron chloride (III), iron sulfate (III), and iron bromide (III), and organic iron (III) complex salts.

When an organic iron (III) complex salt is used, examples of the complex-forming compounds for the iron (III) complex salt include acetic acid, citric acid, oxalic acid, salicylic acid, diethyldithiocarbaminc acid, succinic acid, tartaric acid, glycolic acid, glycine, alanine, aspartic acid, thioglycol acid, ethylenediamine, trimethylenediamine, diethylene glycol, triethylene glycol, 1,2-ethanedithiol, malonic acid, glutaric acid, 3-hydroxybutyric acid, propionic acid, phthalic acid, isophthalic acid, 3-hydroxysalicylic acid, 3,5-dihydroxysalicylic acid, gallic acid, benzoic acid, maleic acid, the salts thereof, and aminopolycarboxylic acids and the salts thereof.

Examples of the amino polycarboxylic acid and the salts thereof include ethylenediamine-N,N,N′,N′-tetraacetic acid, diethylenetriaminepentaacetic acid, 1,3-diaminopropane-N,N,N′,N′-tetraacetic acid, 1,2-diaminopropane-N,N,N′,N′-tetraacetic acid, ethylenediamine-N,N′-disuccinic acid (racemic body), ethylenediaminedisuccinic acid (SS isomer), N-(2-carboxylatoethyl)-L-aspartic acid, N-(carboxymethyl)-L-aspartic acid, β-alaninediacetic acid, methyliminodiacetic acid, nitrilotriacetic acid, cyclohexanediaminetetraacetic acid, iminodiacetic acid, glycol ether diamine-tetraacetic acid, ethylenediamine-1-N,N′-diacetic acid, ethylenediamine-ortho-hydroxyphenlylacetic acid, N,N-bis(2-hydroxybenzyl)ethylenediamine-N,N-diacetic acid, and the like, and the salts thereof. The counter salt is preferably an alkali-metal salt or an ammonium salt, particularly preferably an ammonium salt.

In particular, hydrogen peroxide, iodate salts, hypochlorite salts, chlorate salts, persulfate salts, and organic iron (III) complex salts are preferable; when an organic iron (III) organic complex salt is used, favorable complex-forming compounds include citric acid, tartaric acid, aminopolycarboxylic acid (specifically, ethylenediamine-N,N,N′,N′-tetraacetic acid, diethylenetriamine pentaacetic acid, 1,3-diaminopropane-N,N,N′,N′-tetraacetic acid, ethylenediamine-N,N′-disuccinic acid (racemic body), ethylenediamine disuccinic acid (SS isomer), N-(2-carboxylatoethyl)-L-aspartic acid, N-(carboxymethyl)-L-aspartic acid, β-alanine diacetic acid, methyliminodiacetic acid, nitrilotriacetic acid, and iminodiacetic acid).

Among the oxidizing agents above, hydrogen peroxide, persulfate salts, and iron (III) ethylenediamine-N,N,N′,N′-tetraacetate, and the complexes of 1,3-diaminopropane-N,N,N′,N′-tetraacetic acid and ethylenediaminedisuccinic acid (SS isomer) are most favorable.

The additive amount of the oxidizing agent is preferably 0.003 mol to 8 mol, more preferably 0.03 mol to 6 mol, and particularly more preferably 0.1 mol to 4 mol, per L of the polishing composition used for polishing. The additive amount of the oxidizing agent is preferably 0.003 mol or more for assuring a CMP rate oxidizing the metal sufficiently and 8 mol or less for prevention of roughening of the polishing face.

The oxidant is preferably used by mixing to a composition containing other components than the oxidant when a polishing liquid is used to polish. A timing when the oxidant is mixed is preferably within 1 hr immediately before the polishing liquid is used, more preferably within 5 min, and particularly preferably within 5 sec immediately before feeding, after disposing a mixer immediate before the polishing liquid is fed in a polishing machine, on a surface to be polished.

<PH of Metal-Polishing Liquid>

The pH of the metal-polishing liquid of the invention is preferably in the range of 4 to 9, more preferably in the range of 5 to 8 and further more preferably in the range of 6 to 8. In the range, the metal-polishing liquid of the invention exerts particularly excellent advantages. The polishing liquid of the invention, at the time of the polishing, may not contain water or may be diluted with water or an aqueous solution. When the polishing liquid is diluted with water or an aqueous solution, the pH in the invention denotes a value after dilution with water or an aqueous solution.

The pH of the metal-polishing liquid of the invention may be set considering the absorptivity to and the reactivity with a surface to be polished of the amino acid derivative, the solubility of the metal to be polished, the electrochemical property of a surface to be polished, a dissociation state of compound functional groups and the stability as a liquid.

The pH of the metal-polishing liquid may be adjusted by adding, for instance, an alkali agent or other organic acids, which are described below. The alkali agent and other organic acids will be detailed below.

<Other Components>

Hereinafter, other components that the metal-polishing liquid of the invention may contain will be described.

—Aromatic Heterocyclic Compound—

The metal-polishing liquid of the invention preferably contains at least one kind of aromatic heterocyclic compound, as a compound that forms a passivation film on a surface of a metal to be polished.

Here, the “aromatic heterocyclic compound” is a compound having a heterocycle containing at least one hetero atom. The “hetero atom” means an atom other than a carbon atom and a hydrogen atom. The heterocycle means a ring compound having at least one hetero atom. The hetero atom means only an atom that constitutes a constituent portion of a ring system of the heterocycle but not an atom located outside of the ring system, nor an atom separated from the ring system via at least one non-conjugate single bond, and nor an atom that is a part of a further substituent of the ring system.

Preferable examples of the hetero atoms include a nitrogen atom, a sulfur atom, an oxygen atom, a selenium atom, a tellurium atom, a phosphorus atom, a silicon atom and a boron atom. More preferable examples thereof include a nitrogen atom, a sulfur atom, an oxygen atom and a selenium atom. Particularly preferable examples thereof include a nitrogen atom, a sulfur atom and an oxygen atom. Most preferable examples thereof include a nitrogen atom and a sulfur atom.

In the beginning, an aromatic heterocycle that is a mother nucleus will be described.

The aromatic heterocyclic compound that is used in the invention, without particularly limiting the number of rings of a heterocycle, may be a monocyclic compound and a polycyclic compound having a condensed ring. The number of members in the case of a monocycle is preferably 3 to 8, more preferably 5 to 7 and particularly preferably 5 and 6. Furthermore, the number of rings in the case of having a condensed ring is preferably in the range of 2 to 4 and more preferably 2 or 3.

Specific examples of the aromatic heterocycles are not particularly limited thereto, but include a pyrrole ring, a thiophene ring, a furan ring, a pyrane ring, a thiopyrane ring, an imidazole ring, a pyrazole ring, a thiazole ring, an isothiazole ring, an oxazole ring, an isoxazole ring, a pyridine ring, a pyradine ring, a pyrimidine ring, a pyridazine ring, a pyrrolidine ring, a pyrazolidine ring, an imidazolidine ring, an isoxazolidine ring, an isothiazolidine ring, a piperidine ring, a piperadine ring, a morpholine ring, a thiomorpholine ring, a chroman ring, a thiochroman ring, an isochroman ring, an isothiochroman ring, an indoline ring, an isoindoline ring, a pilindine ring, an indolizine ring, an indole ring, an indazole ring, a purine ring, a quinolizine ring, an isoquinoline ring, a quinoline ring, a naphthylidine ring, a phthalazine ring, a quinoxaline ring, a quinazoline ring, a cinnoline ring, a pteridine ring, an acridine ring, a pipemidine ring, a phenanthroline ring, a carbazole ring, a carboline ring, a phenazine ring, an antilysine ring, a thiadiazole ring, an oxadiazole ring, a triazine ring, a triazole ring, a tetrazole ring, a benzoimidazole ring, a benzoxazole ring, a benzothiazole ring, a benzothiadiazole ring, a benzofuroxan ring, a naphthoimidazole ring, a benzotriazole ring and a tetraazaindene ring, and more preferably include a triazole ring and a tetrazole ring.

Next, substituents, that the aromatic heterocyclic ring may have, will be described.

In the present invention, when a particular portion is referred to as a “group”, the portion itself may not be substituted but may be substituted by at least one kind (up to a possible maximum number) of substituent groups. For instance, an “alkyl group” means a substituted or non-substituted alkyl group.

The substituent groups that an aromatic heterocyclic compound may have include, for example, the following ones, without restricting thereto.

Examples thereof include halogen atoms (fluorine atom, chlorine atom, bromine atom, or iodine atom), alkyl groups (linear-chain, branched, or cyclic alkyl groups, which may be polycyclic alkyl groups like a bicycloalkyl group, or may include an active methine group), alkenyl groups, alkynyl groups, aryl groups, heterocyclic groups (substituted position is not limited), acyl groups, alkoxycarbonyl groups, aryloxycarbonyl groups, heterocyclic oxycarbonyl groups, carbamoyl groups (carbamoyl groups having a substituent include, for example, N-hydroxycarbamoyl group, N-acylcarbamoyl group, N-sulfonylcarbamoyl group, N-carbamoylcarbamoyl group, thiocarbamoyl group, and N-sulfamoylcarbamoyl group), carbazoyl groups, carboxyl groups or salts thereof, oxalyl groups, oxamoyl groups, cyano groups, carboneimidoyl groups, formyl groups, hydroxy groups, alkoxy groups (including groups repeatedly containing an ethyleneoxy group or propyleneoxy group unit), aryloxy groups, heterocycloxy groups, acyloxy groups, (alkoxy or aryloxy)carbonyloxy groups, carbamoyloxy groups, sulfonyloxy groups, amino groups, (alkyl, aryl, or heterocyclic)amino groups, acylamino groups, sulfonamide groups, ureido groups, thioureido groups, N-hydroxyureido groups, imido groups, (alkoxy or aryloxy)carbonylamino groups, sulfamoylamino groups, semicarbazide groups, thiosemicarbazide groups, hydrazino groups, ammonio groups, oxamoylamino groups, N-(alkyl or aryl)sulfonylureido groups, N-acylureido groups, N-acylsulfamoylamino groups, hydroxyamino groups, nitro groups, heterocyclic groups containing a quatemized nitrogen atom (such as a pyridinio group, imidazolio group, quinolinio group, isoquinolinio group), isocyano groups, imino groups, mercapto groups, (alkyl, aryl, or heterocyclic)thio groups, (alkyl, aryl, or heterocyclic)dithio groups, (alkyl or aryl)sulfonyl groups, (alkyl or aryl)sulfinyl groups, sulfo groups or salts thereof, sulfamoyl groups (sulfamoyl groups having a substituent include, for example, an N-acylsulfamoyl group and N-sulfonylsulfamoyl group) or salts thereof, phosphino groups, phosphinyl groups, phosphinyloxy groups, phosphinylamino groups, and silyl groups.

Now, the “active methine group” means a methine group substituted by two electron drawing groups. The “electron drawing group” means, for instance, an acyl group, an alkoxycarbonyl group, an aryloxycarbonyl group, a carbamoyl group, an alkylsulfonyl group, an arylsulfonyl group, a sulfamoyl group, a trifluoromethyl group, a cyano group, a nitro group and a carbonimidoyl group. Furthermore, two electron drawing groups may combine each other to form a ring structure. Still furthermore, the “salt” means a positive ion of an alkali metal, an alkaline earth metal or a heavy metal or an organic positive ion such as ammonium ion or a phosphonium ion.

Among them, examples of preferable substituents in aromatic heterocyclic compounds include halogen atoms (a fluorine atom, chlorine atom, bromine atom, or iodine atom), alkyl groups (linear-chain, branched, or cyclic alkyl groups, which may be polycyclic alkyl groups such as a bicycloalkyl group, or may include an active methine group), alkenyl groups, alkynyl groups, aryl groups, heterocyclic groups (substituted position is not limited), acyl groups, alkoxycarbonyl groups, aryloxycarbonyl groups, heterocyclic oxycarbonyl groups, carbamoyl groups, N-hydroxycarbamoyl groups, N-acylcarbamoyl groups, N-sulfonylcarbamoyl groups, N-carbamoylcarbamoyl groups, thiocarbamoyl groups, N-sulfamoylcarbamoyl groups, carbazoyl groups, oxalyl groups, oxamoyl groups, cyano groups, carboneimidoyl groups, formyl groups, hydroxy groups, alkoxy groups (include groups repeatedly containing an ethyleneoxy group or propyleneoxy group unit), aryloxy groups, heterocycloxy groups, acyloxy groups, (alkoxy or aryloxy)carbonyloxy groups, carbamoyloxy groups, sulfonyloxy groups, (alkyl, aryl, or heterocyclic)amino groups, acylamino groups, sulfoneamide groups, ureido groups, thioureido groups, N-hydroxyureido groups, imido groups, (alkoxy or aryloxy)carbonylamino groups, sulfamoylamino groups, semicarbazide groups, thiosemicarbazide groups, hydrazino groups, ammonio groups, oxamoylamino groups, N-(alkyl or aryl)sulfonylureido groups, N-acylureido groups, N-acylsulfamoylamino groups, hydroxyamino groups, nitro groups, heterocyclic groups containing a quaternized nitrogen atom (such as a pyridinio group, imidazolio group, quinolinio group, isoquinolinio group), isocyano groups, imino groups, mercapto groups, (alkyl, aryl, or heterocyclic)thio groups, (alkyl, aryl, or heterocyclic)dithio groups, (alkyl or aryl)sulfonyl groups, (alkyl or aryl)sulfinyl groups, sulfo groups or salts thereof, sulfamoyl groups, N-acylsulfamoyl groups, N-sulfonylsulfamoyl groups or salts thereof, phosphino groups, phosphinyl groups, phosphinyloxy groups, phosphinylamino groups or silyl groups.

Now, the active methine group means a methine group substituted by two electron drawing groups, and the electron drawing group means, for instance, an acyl group, an alkoxycarbonyl group, an aryloxycarbonyl group, a carbamoyl group, an alkylsulfonyl group, an arylsulfonyl group, a sulfamoyl group, a trifluoromethyl group, a cyano group, a nitro group and a carbonimidoyl group.

Further, preferable examples thereof include halogen atoms (a fluorine atom, chlorine atom, bromine atom, or iodine atom), alkyl groups (linear-chain, branched, or cyclic alkyl groups, which may be polycyclic alkyl groups such as a bicycloalkyl group, or may include an active methine group), alkenyl groups, alkynyl groups, aryl groups and heterocyclic groups (substituted position is not limited).

Two of the above-mentioned substituents may combine with each other to form a ring (aromatic or non-aromatic hydrocarbon ring or aromatic heterocyclic ring), which may further combine to form a polycyclic condensed ring. Examples thereof include a benzene ring, a naphthalene ring, an anthracene ring, a phenanthrene ring, a fluorene ring, a triphenylene ring, a naphthacene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophene ring, an isobenzofuran ring, a quinolizine ring, a quinoline ring, a phthalazine ring, a naphthyridine ring, a quinoxaline ring, a quinoxazoline ring, an isoquinoline ring, a carbazole ring, a phenanthridine ring, an acridine ring, a phenanthroline ring, a thianthrene ring, a chromene ring, a xanthene ring, a phenoxathiin ring, a phenothiazine ring and a phenazine ring.

Specific examples of aromatic heterocyclic compounds include, without restricting thereto, the following ones.

That is, 1,2,3,4-tetrazole, 5-amino-1,2,3,4-tetrazole, 5-methyl-1,2,3,4-tetrazole, 1,2,3-triazole, 4-amino-1,2,3-triazole, 4,5-diamino-1,2,3-triazole, 1,2,4-triazole, 3-amino-1,2,4-triazole, 3,5-diamino-1,2,4-triazole and benzotriazole can be cited.

Preferable examples of (a) 1,2,3,4-tetrazole, (b) 1,2,3-triazole and (c) 1,2,4-triazole that are cited as aromatic heterocyclic compounds preferably used in the invention.

(a) As preferable 1,2,3,4-tetrazole derivatives, ones that do not have a substituent on a nitrogen atom that forms a ring and have a particular substituent at the 5 position can be cited.

(b) As preferable 1,2,3-triazole derivatives, ones that do not have a substituent on a nitrogen atom that forms a ring and have a particular substituent on 4 and/or 5 position can be cited.

(c) As preferable 1,2,4-triazole derivatives, ones that do not have a substituent on a nitrogen atom that forms a ring and have a particular substituent on 2 and/or 5 position can be cited.

(a) Examples of substituent groups that 1,2,3,4-tetrazole has at the 5 position include a substituent group selected from a sulfo group, an amino group, a carbamoyl group, a carbonamide group, a sulfamoyl group and a sulfone amide group, and an alkyl group substituted by at least one substituent selected from a hydroxy group, a carboxyl group, a sulfo group, an amino group, a carbamoyl group, a carbon amide group, a sulfamoyl group and a sulfone amide group. More preferable are alkyl groups substituted by at least one substituent selected from a hydroxy group, a carboxyl group, a sulfo group, an amino group and a carbamoyl group. The alkyl group may have other substituents, as long as it has at least one of the above-listed substituents.

More preferable examples of the (a) 1,2,3,4-tetrazole derivatives having a substituent at the 5 position include tetrazole derivatives containing an alkyl group substituted by at least one of a hydroxy group or a carboxyl group as a substituent. Still more preferable examples include tetrazole derivatives that contain an alkyl group substituted by at least one carboxyl group as a substituent. Examples of such 1,2,3,4-tetrazole derivatives include 1H-tetrazole-5 acetic acid and 1H-tetrazole-5-succinic acid.

Examples of substituents that 1,2,3-trizole may have at the 4 and/or 5 position include a substituent selected from a hydroxy group, a carboxyl group, a sulfo group, an amino group, a carbamoyl group, a carbonamide group, a sulfamoyl group and a sulfone amide group or an alkyl group or an aryl group substituted by at least one substituent selected from a hydroxy group, a carboxyl group, a sulfo group, an amino group, a carbamoyl group, a carbon amide group, a sulfamoyl group and a sulfone amide group. More preferable are substituents selected from a hydroxy group, a carboxyl group, a sulfo group and an amino group or an alkyl group substituted by at least one substituent selected from a hydroxy group, a carboxyl group, a sulfo group and an amino group. The alkyl group and aryl group, may have other substituents, as long as they have at least one of the above-listed substituents. Furthermore, one obtained by substituting either one of the 4 and 5 positions of 1,2,3-triazole is preferred.

Preferable examples of (b) 1,2,3-triazole derivatives having a substituent at the 4 and/or 5 position include 1,2,3-triazole derivatives containing a substituent selected from a hydroxy group and a carboxyl group, and an alkyl group substituted by at least either of a hydroxy group or a carboxy group. Still more preferable examples include 1,2,3-triazole derivatives that include a carboxyl group or an alkyl group substituted by at least one carboxyl group as a substituent. Examples of such 1,2,3-triazole derivatives include 4-carboxy-1H-1,2,3-triazole, 4,5-dicarboxy-1H-1,2,3-triazole, 1H-1,2,3-triazole-4-acetic acid and 4-carboxy-5-carboxymethyl-1H-1,2,3-triazole.

(c) Examples of substituents that 1,2,4-triazole may have at the 3 and/or 5 position include a substituent selected from a sulfo group, a carbamoyl group, a carbonamide group, a sulfamoyl group and a sulfone amide group, and an alkyl group or aryl group substituted by at least one substituent selected from a hydroxy group, a carboxyl group, a sulfo group, an amino group, a carbamoyl group, a carbon amide group, a sulfamoyl group and a sulfone amide group. More preferable are alkyl groups substituted by at least one substituent selected from a hydroxy group, a carboxyl group, a sulfo group and an amino group. The alkyl group and aryl group may have other substituents as long as they have at least one of the above-listed substituents. Furthermore, one obtained by substituting either one of the 3 and 5 positions of (c) 1,2,4-triazole is preferred.

Preferable examples of the (c) 1,2,4-triazole derivatives having a substituent at 3 and/or 5 position include 1,2,4-triazole derivatives containing an alkyl group substituted by at least one of a hydroxy group and a carboxyl group as a substituent. More preferable examples include 1,2,4-triazole derivatives that include at least an alkyl group substituted by at least one carboxyl group as a substituent. Examples of such 1,2,4-triazole derivatives include 3-carboxy-1,2,4-triazole, 3,5-dicarboxy-1,2,4-triazole and 1,2,4-triazole-3-acetic acid.

Hereinafter, specific examples of (a) 1,2,3,4-tetrazole derivatives, (b) 1,3,4-triazole derivatives and (c) 1,2,4-triazole derivatives are cited without restricting the invention thereto.

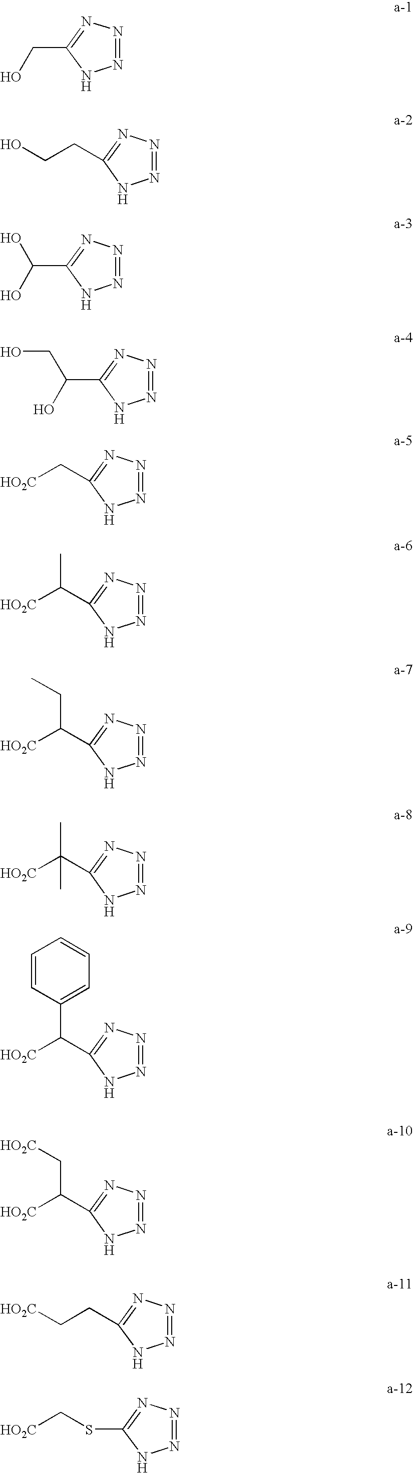

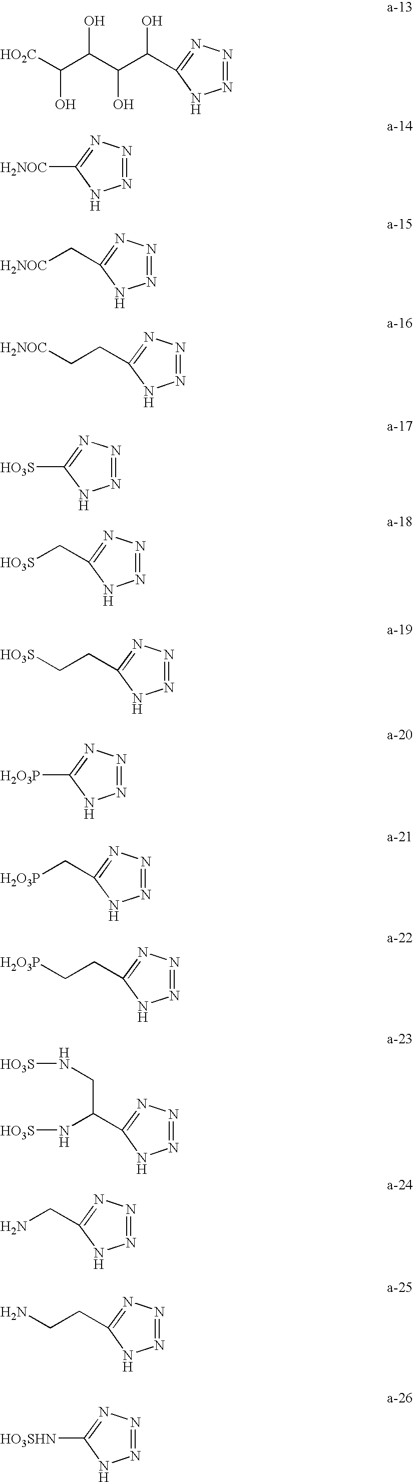

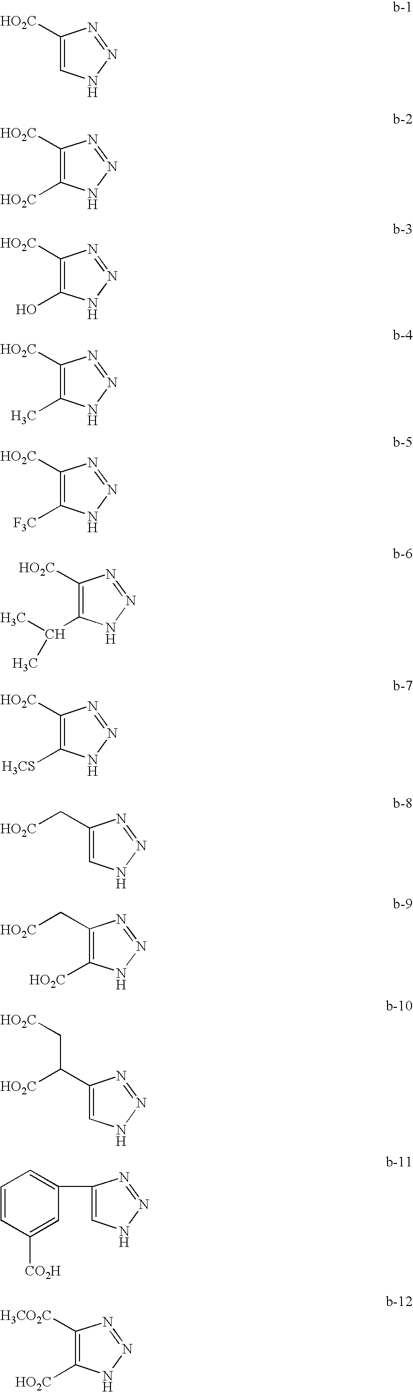

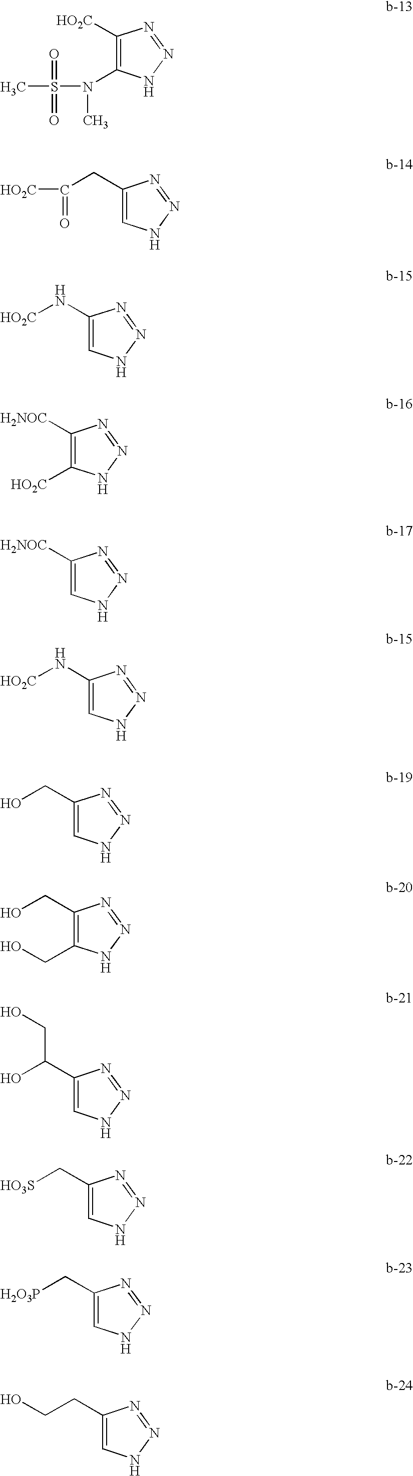

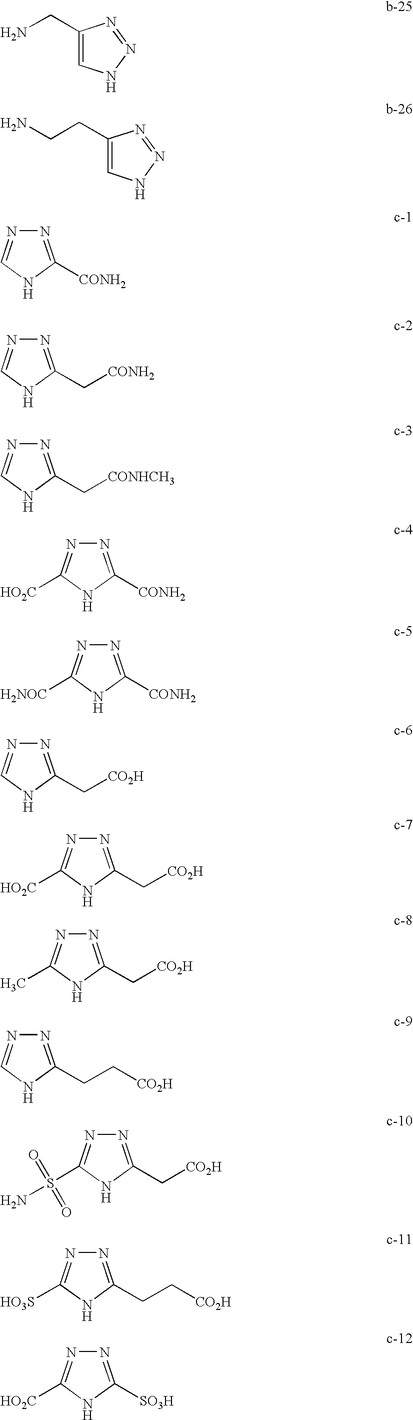

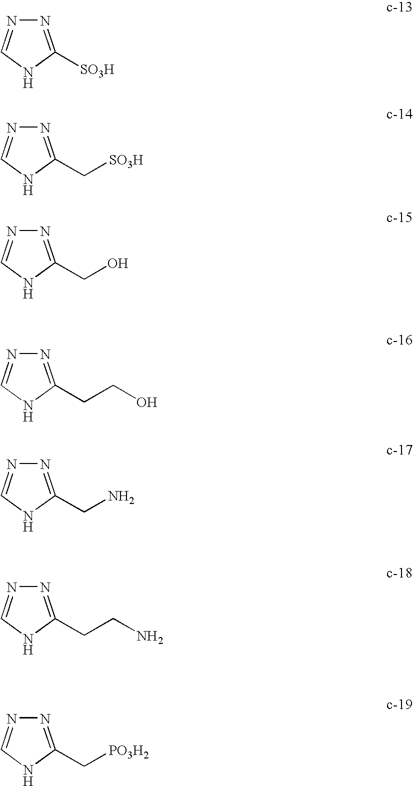

Aromatic heterocyclic compounds may be used alone or in combination of at least two kinds thereof. Furthermore, the aromatic heterocyclic compounds may be synthesized according to a standard method and commercially available products may be used.

The metal-polishing liquid of the invention particularly preferably contains tetrazole or a derivative thereof, among the above described aromatic heterocyclic compounds, from the viewpoint of being excellent in the suppressibility to the chemical dissolution of the metal wiring.

A content of the aromatic heterocyclic compound in the metal-polishing liquid of the invention is preferably in the range of 0.0001 to 1.0 mol, more preferably in the range of 0.0005 to 0.5 mol and still more preferably in the range of 0.0005 to 0.05 mo, as a total amount, in 1 L of the metal-polishing liquid at the time of polishing (that is, when it is diluted with water or an aqueous solution, diluted metal-polishing liquid).

—Chelating Agent—

In the metal-polishing liquid of the invention, in order to reduce an adverse effect of mingling polyvalent metal ions, as needed, a chelating agent (that is, a water softener) is preferably contained.

Such a chelating agent may be general-purpose water softeners serving as a precipitation inhibitor of calcium or magnesium or analogous compounds thereof, and specific examples thereof include nitrilotriacetic acid, diethylene-triamine-pentaacetic acid, ethylenediamine-tetraacetic acid, N,N,N-trimethylene-phosphonic acid, ethylenediamine-N,N,N′,N′-tetramethylene-sulfonic acid, trans-cyclohexane-diamine-tetraacetic acid, 1,2-diamino-propane-tetraacetic acid, glycol ether diamine-tetraacetic acid, ethylenediamine-o-hydroxy-phenyl acetic acid, ethylenediamine disuccinic acid (SS form), N-(2-carboxylate ethyl)-L-aspartic acid, β-alanine diacetic acid, 2-phosphonobutane-1,2,4-tricarboxylic acid, 1-hydroxy-ethylidene-1,1-diphosphonic acid, N,N′-bis(2-hydroxybenzyl)ethylenediamine-N,N′-diacetic acid and 1,2-dihydroxybenzene-4,6-disulfonic acid.

The chelating agents may be used alone or, as needed, in a combination of at least two of them.

An addition amount of the chelating agent may be an amount sufficient for sequestering metal ions such as contaminated polyvalent metal ions; accordingly, the chelating agent is added so as to be in the range of 0.003 to 0.07 mol in 1 L of the metal polishing liquid at the time of the polishing.

—Surfactant and/or Hydrophilic Polymer—

The metal-polishing liquid of the invention preferably contains a surfactant and/or a hydrophilic polymer. Both the surfactant and the hydrophilic polymer have an action to reduce the contact angle on the polishing face and to facilitate uniform polishing.

The surfactant and/or hydrophilic polymer is preferably in the acid type, and, if it is in the salt structure, it is preferably a ammonium salt, potassium salt, sodium salt, or the like, particularly preferably an ammonium or potassium salt.

Anionic surfactants include carboxylate salts, sulfonate salts, sulfate ester salts, and phosphate ester salts: carboxylate salts including soaps, N-acylamino acid salts, polyoxyethylene or polyoxypropylene alkylether carboxylate salts, and acylated peptides; sulfonate salts including alkylsulfonate salts, alkylbenzene and alkylnaphthalenesulfonate salts, naphthalenesulfonate salts, sulfoscuccinate salts, α-olefin sulfonate salts, and N-acyl sulfonate salts; sulfate ester salts including sulfated oils, alkyl sulfate salts, alkylether sulfate salts, polyoxyethylene or polyoxypropylene alkylallylether sulfate salts, and alkyl amide sulfate salts; and phosphate ester salts including alkylphosphate salts and polyoxyethylene or polyoxypropylene alkylallylether phosphate salts.

Cationic surfactants include aliphatic amine salts, aliphatic quaternary ammonium salts, benzalkonium chloride salt, benzethonium chloride, pyridinium salts, and imidazolinium salts; and amphoteric surfactants include carboxybetaine-type, sulfobetaine type, aminocarboxylate salts, imidazolinium betaines, lecithins, and alkylamine oxides.

Nonionic surfactants include ether-type, ether ester-type, ester-type, nitrogen-containing-type; ether-type surfactants including polyoxyethylene alkyl and alkylphenylethers, alkyl allyl formaldehyde-condensed polyoxyethylene ethers, polyoxyethylene polyoxypropylene block polymer, and polyoxyethylene polyoxypropylene alkylethers; ether ester-type surfactants including glycerin ester polyoxyethylene ether, sorbitan ester polyoxyethylene ether, and sorbitol ester polyoxyethylene ether; ester-type surfactants including polyethylene glycol fatty acid esters, glycerin esters, polyglycerin esters, sorbitan esters, propylene glycol esters, and sucrose esters; nitrogen-containing surfactants including fatty acid alkanol amides, polyoxyethylene fatty acid amides, and polyoxyethylene alkyl amides; and the like.

In addition, fluorochemical surfactants and others are also included.

Furthermore, example of other surfactants, hydrophilic compounds and hydrophilic polymers include esters such as glycerin esters, sorbitan esters, methoxy-acetic acid, ethoxy-acetic acid, 3-ethoxy-propionic acid and alanine ethyl ester; ethers such as polyethylene glycol, polypropylene glycol, polytetramethylene glycol, polyethylene glycol alkyl ethers, polyethylene glycol alkenyl ethers, alkyl polyethylene glycols, alkyl polyethylene glycol alkyl ethers, alkyl polyethylene glycol alkenyl ethers, alkenyl polyethylene glycols, alkenyl polyethylene glycol alkyl ethers, alkenyl polyethylene glycol alkenyl ethers, polypropylene glycol alkyl ethers, polypropylene glycol alkenyl ethers, alkyl polypropylene glycols, alkyl polypropylene glycol alkyl ethers, alkyl polypropylene glycol alkenyl ethers, alkenyl polypropylene glycols, alkenyl polypropylene glycol alkyl ethers and alkenyl polypropylene glycol alkenyl ethers; polysaccharides such as alginic acid, pectic acid, carboxymethyl cellulose, curdlan and pullulan; amino acid salts such as ammonium salt of glycine and sodium salt of glycine; polycarboxylic acids and salts thereof such as polyaspartic acid, polyglutamic acid, polylysine, polymalic acid, polymethacrylic acid, ammonium salt of polymethacrylic acid, sodium salt of polymethacrylic acid, polyamide acids, polymaleic acid, polyitaconic acid, polyfumaric acid, poly(p-styrene carboxylic acid), polyacrylic acid, polyacrylamide, amino polyacrylamide, ammonium salt of polyacrylic acid, sodium salt of polyacrylic acid, polyamido acid, ammonium salt of polyamido acid, sodium salt of polyamido acid and polyglyoxylic acid; vinylic polymers such as polyvinyl alcohol, polyvinyl pyrrolidone and polyacrolein; sulfonic acids and salts thereof such as ammonium salt of methyl taurine acid, sodium salt of methyl taurine acid, sodium salt of methyl sulfate, ammonium salt of ethyl sulfate, ammonium salt of butyl sulfate, sodium salt of vinyl sulfonate, sodium salt of 1-allyl sulfonate, sodium salt of 2-allyl sulfonate, sodium salt of methoxy-methyl sulfonate, ammonium salt of ethoxy-methyl sulfonate, sodium salt of 3-ethoxy-propyl sulfonate, sodium salt of methoxy-methyl sulfonate, ammonium salt of ethoxy-methyl sulfonate, sodium salt of 3-ethoxy-propyl sulfonate and sodium sulfo-succinate; and amides such as propionamide, acrylamide, methyl urea, nicotinamide, succinic acid amide and sulfanilamide.

However, when the base substance to be processed is for example a silicon substrate for semiconductor integrated circuit, contamination with an alkali metal, alkali-earth metal, or halide is undesirable, thus, the foregoing additives are desirably acids and ammonium salts thereof. The surfactant is arbitrary, if the base substance is for example glass. Among the exemplary compounds above, ammonium salt of polyacrylic acid, polyvinyl alcohol, succinic acid amide, polyvinyl pyrrolidone, polyethylene glycol, polyoxyethylene polyoxy-propylene block copolymer are more preferable.

The total additive amount of the surfactant and/or the hydrophilic polymer is preferably 0.001 to 10 g, more preferably 0.01 to 5 g, and particularly preferably 0.1 to 3 g, in the polishing composition per L used in polishing. Namely, the additive amount of the surfactant and/or the hydrophilic polymer is preferably 0.001 g or more for favorable effect, and 10 g or less for prevention of decrease in CMP velocity.

The weight-average molecular weight of the surfactant and/or the hydrophilic polymer is preferably in the range of from 500 to 100,000, particularly preferably in the range of from 2,000 to 50,000.

The surfactants may be used alone or in combination of two or more, and surfactants different in kind may be used in combination.

—Alkali Agent, Buffering Agent, And Other Organic Acids—

The metal-polishing liquid of the present invention may, in accordance with objects, within a range that does not impair the effects of the invention, contain an alkali agent, a buffering agent and other organic acid. Hereinafter, the alkali agents, buffering agents and other organic acids, which may be used in the invention will be described.

(Alkali Agent, Buffering Agent)

Furthermore, the metal-polishing liquid of the invention, as needed, may contain an alkali agent for adjusting the pH and a buffering agent from the viewpoint of inhibiting the pH from fluctuating.

Examples of such alkaline agents and buffering agents include non-metallic alkali agents such as organic ammonium hydroxide such as ammonium hydroxide and tetramethyl-ammonium hydroxide, and alkanol-amines such as diethanolamine, triethanolamine and tri-isopropanol-amine; alkali metal hydroxides such as sodium hydroxide, potassium hydroxide, and lithium hydroxide; carbonates, phosphates, borates, tetraborates, hydroxy-benzoate, glycylates, N,N-dimethyl glycylates, leucine salts, norleucine salts, guanine salts, 3,4-dihydroxy-phenylalanine salts, alanine salts, amino-butyl lactate, 2-amino-2-methyl-1,3-propanediol salts, valine salts, proline salts, tris(hydroxy)amino-methane salts and lysine salts.

Specific examples of such alkaline agents and buffering agents include sodium hydroxide, potassium hydroxide, lithium hydroxide, sodium carbonate, potassium carbonate, sodium bicarbonate, potassium bicarbonate, tri-sodium phosphate, tri-potassium phosphate, di-sodium phosphate, di-potassium phosphate, sodium borate, potassium borate, sodium tetraborate (borax), potassium tetraborate, sodium o-hydroxy-benzoate (sodium salicylate), potassium o-hydroxy-benzoate, sodium 5-sulfo-2-hydroxy-benzoate (sodium 5-sulfosalicylate), potassium 5-sulfo-2-hydroxy-benzoate (potassium 5-sulfosalicylate), and ammonium hydroxide.

Particularly preferable examples of the alkaline agents include ammonium hydroxide, potassium hydroxide, lithium hydroxide and tetramethyl-ammonium hydroxide.

Addition amounts of the alkaline agents and buffering agents are not particularly limited as long as pH may be maintained in a preferable range, and this is preferably in the range of 0.0001 to 1.0 mol and more preferably in the range of 0.003 to 0.5 mol with respect to 1 L of the polishing liquid used in the polishing.

In the invention, from the viewpoints of the fluidity of the liquid and the stability of the polishing performance, the specific gravity of the metal-polishing liquid is set preferably in the range of 0.8 to 1.5 and more preferably in the range of 0.95 to 1.35.

(Other Organic Acid)

Furthermore, the metal-polishing liquid of the invention, as needed, may contain other organic acid to adjust the pH. The “other organic acid” here is a compound different in structure from that of the particular amino acid derivative and the oxidant according to the invention and does not include acids that work as the oxidant.

As other organic acids, ones selected from a group below is preferable.

That is, examples thereof include formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, salts such as ammonium salts or alkali metal salts of these acids, sulfuric acid, nitric acid, ammonia or ammonium salts, or mixtures thereof.

An addition amount of other organic acid may be set in the range of 0.00005 to 0.0005 mol in 1 L of the metal-polishing liquid used at the time of polishing.

The metal-polishing liquid of the invention may be used in a polishing method of the invention described below.

[Polishing Method]

In the polishing method of the invention, in a producing step of semiconductor devices, a substrate having a conductor film made of copper or a copper alloy is chemical mechanically polished by use of the metal-polishing liquid of the invention.

The metal-polishing liquid used in the polishing method according to the invention may be a concentrated solution that is diluted with water before use, a combination of aqueous solutions of respective components that are mixed and as needed diluted with water before use, or a diluted solution immediately for use. The metal-polishing liquid in the invention, without particularly restricting, may be used in any of the modes.

According to the polishing method of the invention, preferable aspect is to polish a substrate surface with a polishing pad which is attached on a polishing platen by moving the polishing pad and the substrate surface to be polished relatively in the state that the substrate surface to be polished is pressed by the polishing pad with pressure of 20 kPa or less while the metal-polishing liquid.

Any common polishing machine having a holder holding a semiconductor substrate having a polishing face and a polishing surface plate carrying a polishing pad connected thereto (which in turn is connected to a variable rotational frequency motor) may be used as the polishing machine.

The polishing pad is not particularly limited, and a common nonwoven fabric, expanded polyurethane, porous fluoroplastics or the like may be used. Furthermore, the polishing pad may be a non-foamed pad or a foamed pad. The former pad is a pad of a hard synthetic-resin bulk material like a plastic plate.

Alternatively, the latter pad is an independent-foam pad (dry foamed), a continuous-foam pad (wet foamed), or a two-layer composite pad (lamination), and the two-layer composite pad (laminated) is preferable. The foaming may be homogeneous or heterogeneous.

The polishing pad may contain additionally a abrasive grain used for polishing (such as ceria, silica, alumina, or resin).

In addition, the polishing pad may be made of a soft or hard resin, and the composite pad (laminated) preferably use resins different in hardness.

Favorable examples of the materials include nonwoven fabric, artificial leather, polyamide, polyurethane, polyester, polycarbonate, and the like.

In addition, lattice-shaped grooves, holes, concentric grooves, spiral grooves, and the like may be formed on the surface in contact with the polishing face.

The polishing conditions are not particularly restricted. However, a line speed of a polishing platen is preferably 1 m/s or more.

Pressure (pressing pressure) when a semiconductor substrate having a surface to be polished (film to be polished) is pressed against the polishing pad is preferably 20 kPa or less. A low pressure condition of 13 kPa or less is more preferred because, with a high polishing speed maintained, the uniformity of the polishing speed within the plane of the wafer and the planarity of the pattern can be preferably improved.

When the pressing pressure exceeds 20 kPa, in some cases, the planarity may be deteriorated. Although the lower limit value of the pressing pressure is not particularly restricted, it is about 2 kPa.

During the polishing process, the metal-polishing liquid is continuously fed by means of a pump to the polishing pad. A feed amount thereof, though not particularly restricted, is preferably controlled so that a surface of the polishing pad is always covered with the polishing liquid. A polished semiconductor substrate is washed thoroughly with running water and water drops attached on the semiconductor substrate are spun off the substrate by use of a spin dryer to carry out drying.

In the polishing method of the invention, an aqueous solution that is used to dilute the metal-polishing liquid is same as the aqueous solution described below. The aqueous solution is water previously containing at least one of an oxidant, an acid, an additive and a surfactant, and a component obtained by sum totaling a component contained in the aqueous solution and a component in the metal-polishing liquid that is diluted serves as a component when the metal-polishing liquid is used to polish. When the metal-polishing liquid is diluted with an aqueous solution and used, a component that is difficult to dissolve can be compounded in the form of the aqueous solution; accordingly, a more concentrated metal-polishing liquid can be prepared.

As a method of adding water or an aqueous solution to a concentrated metal-polishing liquid to carry out diluting, there is a method where a pipe that feeds the concentrated metal-polishing liquid and a pipe that feeds water or an aqueous solution are flowed together on the way to carry out mixing and the mixed and diluted metal-polishing liquid is fed to a polishing pad. When the liquids are mixed, commonly applied methods such as a method where, under pressure, liquids are forced to flow through a narrow path to collide with each other to mix the liquids, a method where, in the pipe, a packing material such as glass tubes is filled, whereby a stream is repeatedly divided, separated and flowed together, or a method where a blade rotated by power is disposed in a pipe may be adopted.

A feed speed of the metal-polishing liquid is preferably in the range of 10 to 1000 ml/min and more preferably, in order to satisfy the in-plane uniformity of the wafer of the polishing speed and the planarity of a pattern, in the range of 170 to 800 ml/min.

As a method where a concentrated metal-polishing liquid is diluted with water or an aqueous solution to use in the polishing, a method where a pipe for feeding a metal-polishing liquid and a pipe for feeding water or an aqueous solution are independently disposed and, from the respective pipes, predetermined amounts of the liquids are fed to a polishing pad to mix and polish there owing to a relative movement of the polishing pad and a surface to be polished may be cited. Furthermore, a method where, after predetermined amounts of concentrated metal-polishing liquid and water or an aqueous solution are put into one vessel and mixed, the mixed metal-polishing liquid is fed to the polishing pad to polish may be applied as well.

In the invention, a method where components to be contained in the metal-polishing liquid are divided into at least two constituents, the constituents are diluted with water or an aqueous solution and fed onto a polishing pad on a polishing platen when they are to be used, and polishing is carried out by relatively moving the surface to be polished and the polishing pad with these kept in contact may be used.

For instance, an oxidant is set as one constituent (A) and an acid, an additive, a surfactant and water are set as one constituent (B), then at the point of use thereof, the constituent (A) and the constituent (B) are diluted with water or an aqueous solution to use.

Furthermore, an additive having low solubility is divided into two constituents (C) and (D). An oxidant, an additive and a surfactant are set as one constituent (C) and an acid, an additive, a surfactant and water are set as one constituent (D), then at the point of use thereof, the constituent (C) and the constituent (D) are diluted with water or an aqueous solution to use.

In this case, three pipes for feeding respectively the constituent (C), the constituent (D) and water or an aqueous solution are necessary. For the dilution and mixing thereof there is a method where the three pipes are connected to one pipe that feeds to the polishing pad and the constituents are mixed in the pipe. In this case, after two of the pipes are connected, the remaining one pipe may be connected thereto. For instance, a method where a constituent that contains an additive difficult to dissolve and the other constituent are mixed, and, after securing a sufficient dissolution time by elongating a mixing path, a pipe for water or an aqueous solution is connected thereto can be used.

As other mixing methods, a method where, as mentioned above, three pipes, respectively, are directly lead to the polishing pad and mixing is carried out by relative movement of the polishing pad and a surface to be polished, and a method where three constituents are mixed in one vessel and a diluted metal-polishing liquid is fed therefrom to the polishing pad can be used. In the polishing methods, when one constituent containing the oxidant is kept at 40° C. or less, the other constituent is heated to a temperature in a range from room temperature to 100° C., and the one constituent and the other constituent or water or an aqueous solution are added and used, a temperature after the mixing can be set at 40° C. or less. This is a preferable method because, when a temperature becomes higher, the solubility becomes higher, and, thereby, the solubility of a raw material having low solubility of the metal-polishing liquid can be increased.

A raw material dissolved by heating the other constituent that does not contain the oxidant in the range of from room temperature to 100° C., upon cooling, precipitates in a solution when the temperature becomes lower; accordingly, when this constituent whose temperature has been low is used, it is necessary to heat it in advance to dissolve the precipitates. For this purpose, means for transporting a heated and dissolved constituent liquid and means for agitating the liquid containing the precipitates, transporting the liquid, and heating the pipe to dissolve the precipitates may be adopted. When the heated constituent heightens a temperature of the one constituent containing the oxidant to 40° C. or more, the oxidant may be decomposed; accordingly, a temperature when the heated constituent and the one constituent that cools the heated constituent and contains the oxidant are mixed is set so as to be 40° C. or less.

Furthermore, in the invention, as mentioned above, the metal-polishing liquid may be divided into two or more and fed onto a polishing surface. In this case, the metal-polishing liquid is preferably divided into a constituent that contains the oxidant and a constituent that contains the acid. Still furthermore, the metal-polishing liquid may be a concentrated liquid and may be fed onto a surface to be polished separately from the dilution water.

A target to be polished according to a polishing method of the invention is a substrate that includes a barrier metal film formed over an entire surface of an interlayer insulating film having concave portions and a conductor film made of copper or a copper alloy formed so as to bury the concave portions on a surface of the barrier metal film. The substrate is a semiconductor substrate and is preferably an LSI having wirings made of copper metal and/or copper alloy, the wiring being particularly preferred to be a copper alloy.

As a body to be worked, which is a polishing target, it is included materials in all steps that necessitate to planarize, in a semiconductor device producing method, such as a wafer where a conductive material film is formed on a support substrate and a laminated body where a conductive material film is formed on an interlayer insulating film disposed on a wiring formed on the support substrate.

Furthermore, among copper alloys, copper alloys containing silver are preferred. A content of silver in the copper alloy is preferably 40% by mass or less, more preferably 10% by mass or less, still more preferably 1% by mass or less, and copper alloys containing silver in the range of 0.00001 to 0.1% by mass exert the most excellent advantage.

In the invention, a semiconductor substrate that is an object of the polishing has, in the case of, for instance, DRAM devices, wirings of, by a half pitch, preferably 0.15 μm or less, more preferably 0.10 μm or less and still more preferably 0.08 μm or less. On the other hand, in the case of MPU devices, an LSI has wirings of, by a half pitch, preferably 0.12 μm or less, more preferably 0.09 μm or less and still more preferably 0.07 μm or less. When, to the LSIs, the metal-polishing liquid of the invention is used, a particularly excellent advantage can be obtained.

(Substrate)

As examples of a substrate used in the invention, ones that are used in an 8-inch or 12-inch semiconductor wafer producing method or a micro-machine producing method may be used. As the kind thereof, silicon wafers for a semiconductor, SOI wafers and sapphire substrates of a compound semiconductor, which are used for semiconductor lasers, are included as well. In addition, the invention can also be used for applications in which a wiring pattern is formed on a substrate of polymer film followed by planarizing.

An object wafer to which the CMP is applied with the metal-polishing liquid of the invention has a diameter of preferably 200 mm or more and particularly preferably 300 mm or more. When the diameter is 300 mm or more, the effects of the invention can be remarkably exerted.

(Interlayer Insulating Film)

As an interlayer insulating film in the invention is preferably a film having the dielectric constant of 2.6 or less and examples thereof include silica-based films and organic interlayer insulating films can be cited. In particular, carbon-doped silica-based films are preferably used. A thickness of an interlayer insulating film in the invention may be appropriately adjusted depending on an upper portion or a lower portion of wirings in a multi-layer wiring or between generations (nodes).

(Barrier Metal Film)

A barrier metal film is a film (layer) disposed between a conductor film (wiring) made of copper or a copper alloy disposed on a semiconductor substrate and an interlayer insulating film to inhibit copper from diffusing.

A material of the barrier layer film is preferably a metal material having low resistance. Specifically, at least one kind selected from tantalum or tantalum compounds, titanium or titanium compounds, tungsten or tungsten compounds and ruthenium is preferably contained. More preferably, any one of TiN, TiW, Ta, TaN, W, WN and Ru is contained, and, among these, Ta or TaN is particularly preferably contained.

A thickness of the barrier metal film is preferably set in the range of approximately from 20 to 30 mn.

Hereinafter, exemplary embodiments of the invention will be listed.
<1> A metal-polishing liquid that is used in chemical mechanical polishing for a conductor film made of copper or a copper alloy during semiconductor device production, wherein the metal-polishing liquid comprises the following components (1), (2) and (3):
(1) an amino-acid derivative represented by the following formula (I)

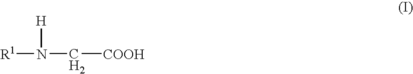

wherein in the formula (I), R¹ represents an alkyl group having 1 to 4 carbon atoms;
(2) colloidal silica in which silicon atoms on a surface thereof are at least partially modified by aluminum atoms; and (3) an oxidant.

<2> The metal-polishing liquid described in the <1>, wherein the (1) amino-acid derivative represented by the formula (I) is N-methylglycine or N-ethylglycine.

<3> The metal-polishing liquid of the <1> or <2>, wherein the (2) colloidal silica in which silicon atoms on a surface thereof are at least partially modified by aluminum atoms has a primary particle diameter in the range of from 20 to 40 nm, and a degree of association thereof is 2 or less.

<4> The metal-polishing liquid of any one of the <1> through <3>, further comprising a tetrazole or derivative thereof.

<5> The metal-polishing liquid of any one of the <1> through <4>, wherein the pH is in the range of from 4 to 9.

<6> A polishing method comprising chemical mechanical polishing a substrate having a conductor film made of copper or a copper alloy with a metal-polishing liquid that contains the following components (1), (2) and (3) during semiconductor device production:
(1) a compound represented by the following formula (I)

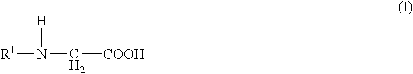

wherein in the formula (I), R¹ represents an alkyl group having 1 to 4 carbon atoms;
(2) colloidal silica in which silicon atoms on a surface thereof are at least partially modified by aluminum atoms; and (3) an oxidant.

<7> The polishing method of the <6>, wherein the polishing comprising polishing a substrate surface with a polishing pad which is attached on a polishing platen by moving the polishing pad and the substrate surface to be polished relatively in a state in which the substrate surface to be polished is pressed by the polishing pad with pressure of 20 kPa or less while the metal-polishing liquid is fed to the polishing pad.

### EXAMPLES

Hereinafter, the present invention will be more specifically described with reference to examples. The invention is not restricted to the examples. Polishing conditions are as follows.

### Preparation of Abrasive Grains (Particles)

### —Preparation of Particular Colloidal Silica (D-1) and (D-2)—

The particular colloidal silica (D-1) was prepared as follows.

Ammonium water was added to 1000 g of an aqueous dispersion of 20% by mass of colloidal silica having an average abrasive grain size of 25 nm, to adjust the pH to 9.0, while agitating at room temperature, followed by slowly adding 15.9 g of a sodium aluminate aqueous solution of which Al₂O₃ concentration is 3.6% by mass and Na₂O/Al₂O₃ molar ratio is 1.50 over for 30 min, further followed by agitating for 0.5 hr. An obtained sol was charged in a SUS autoclave apparatus, after heating at 130° C. for 4 hr, passed through overnight a column packed with a hydrogen-type strongly acidic cation exchange resin (trade name: Amberlite IR-120B) and a column packed with a hydroxy group-type strongly basic anion exchange resin (trade name: Amberlite IRA-410) at a space rate of 1 h⁻¹ at room temperature, and an initial fraction was cut.

The particular colloidal silica (D-2) was prepared as follows.

In the preparation of the particular colloidal silica (D-1), without heating, an obtained sol was passed through overnight a column packed with a hydrogen-type strongly acidic cation exchange resin (trade name: Amberlite IR-120B) and a column packed with a hydroxy group-type strongly basic anion exchange resin (trade name: Amberlite IRA-410) at a space rate of 1 h⁻¹ at room temperature, and an initial fraction was cut.

According to the above methods, the particular colloidal silica (D-1) and (D-2) shown in Table 1 were prepared. The particular colloidal silica (D-1) and (D-2) did not show, after the preparation, the thickening and gelation.

TABLE 1

| | | | Number of |
|---|---|---|---|
| | | | Introduced |
| | | | Aluminum |
| Particular | | | Atoms/Number of |
| Colloidal | Primary Grain | | Surface Silicon |
| Silica | Diameter (nm) | Surface Modifier | Atom Sites (%) |
| D-1 | 25 | Sodium Aluminate | 1 |
| D-2 | 25 | Sodium Aluminate | 1 |

### Polishing Conditions

As a polishing apparatus, an apparatus LPG-612 (trade name, produced by Lapmaster SFT Corp) was used to polish under the following conditions. Specifically, with slurry of the metal-polishing liquid described below feeding on a polishing pad of a polishing platen of the polishing apparatus and with a polishing substrate pressed against the polishing pad, the polishing platen and the substrate were relatively moved to polish a metal film.

Table rotational frequency: 64 rpm

Head rotational frequency: 65 rpm

Polishing pressure: 13 kPa

Polishing pad: IC-1400 (trade name, produced by Rodel Nitta Company)

Slurry supply rate: 200 ml/min

As a substrate, an 8-inch wafer where a silicon oxide film (insulating film) was patterned by means of a photolithography process and a reactive ion etching process to form a wiring groove having a width of 0.09 to 100 μm and a depth of 600 μnm and a connecting hole (concave portion), followed by forming a Ta film (barrier metal film) having a thickness of 20 nm by means of a sputtering process, further followed by forming a copper film having a thickness of 50 nm by means of a sputtering process, still further followed by forming a copper film (conductor film) having a thickness of 1000 nm in total by means of a plating process was used.

[Evaluation Items]

### 1. Polishing Speed

### —Measurement of Polishing Speeds of Copper and Ta Films—

A film thickness difference before and after the CMP of copper and Ta films that are a conductor film and a barrier metal film was obtained by calculating from values of the electric resistance.

The film thickness difference was measured by use of VR-200 (trade name, produced by Kokusai Electric alpha Co., Ltd.). Specifically, polishing speed (nm/min)=[(thickness of copper and Ta films prior to polishing)−(thickness of copper and Ta films after polishing)]/polishing time, was used for calculation.

### 2. Polishing Speed Ratio of Copper/Tantalum

The polishing speed obtained in the above 1 was inserted in a formula below and thereby a polishing speed ratio of copper/tantalum (copper/tantalum polishing selectivity) was calculated.

(Polishing speed ratio of copper/tantalum)=(average polishing speed of copper)/(average polishing speed of tantalum)

### 3. Dishing

By use of an apparatus “LGP-612” (trade name, produced by Lapmaster SFT Corp) as a polishing apparatus, under the above mentioned conditions and with the above-mentioned substrate, a film disposed on a patterned wafer was polished while slurry was fed, and a step at that time was measured as shown below.

Measurement of step: By use of a needle-contacting-type profilometer, a step at L/S of 100 μm/100 μm was measured.

### EXAMPLE 1

-Composition of Metal Polishing Liquid-

| | | |
|---|---|---|
| Aromatic heterocyclic compound: tetrazole | 0.01% | by mass |
| Component (1): exemplified compound (A-1) | 0.01% | by mass |
| (particular amino-acid derivative with | | |
| a structure shown above, produced by | | |
| Wako Pure Chemical Industries Ltd.,) | | |
| Component (2): particular colloidal | 0.5% | by mass |
| silica (D-1) | | |
| Component (3): H₂O₂ (oxidant) | 1% | by mass |

| | |
|---|---|
| pH (adjusted by ammonia water and | 7.5 |
| sulfuric acid) | |

An aqueous solution was prepared so that the respective components exhibited the above-mentioned concentrations, followed by agitating by use of a high-performance homogenizer to carry out uniform dispersion, whereby a metal-polishing liquid of example 1 was obtained.

By use of the obtained metal-polishing liquid, the polishing was conducted under the above mentioned conditions, followed by evaluating the items. Evaluation results are shown in Table 2.

### EXAMPLES 2 AND 3, COMPARATIVE EXAMPLE 1

Similarly to example 1, respectively using the organic acids and abrasive grain components described in Table 2, metal-polishing liquids of examples 2 and 3 and comparative example 1 were prepared and subjected to a polishing test. The aromatic heterocyclic compound, oxidant and pH were set the same as in example 1. Particular amino-acid derivatives (A-2) and (A-3) are compounds that were described as specific examples of the particular amino-acid derivatives.

Using the obtained metal-polishing liquid, the polishing was applied under the above-mentioned conditions, followed by evaluating the above-mentioned evaluation items. Evaluation results are shown in Table 2.

TABLE 2

| | Metal-polishing Liquid | | | | | | Evaluation | | |
|---|---|---|---|---|---|---|---|---|---|
| | Particular | | | | | | | Copper/Tan | |
| | Amino-acid | Abrasive Component | | | | | Copper | talum | |
| | Derivative | | | Grain | | | Polishing | Polishing | |
| | or Reference | | Content (% | Diameter | Degree of | | Speed | Speed | Dishing |
| | Compound | Kind | by mass) | (nm) | Association | pH | (nm/min) | Ratio | (nm) |
| Example 1 | A-1 | D-1 | 0.5 | 25 | 2 | 6.5 | 530 | 420 | 57 |
| Example 2 | A-3 | D-1 | 0.5 | 25 | 1 | 6.2 | 380 | 410 | 53 |
| Example 3 | A-2 | D-2 | 0.5 | 25 | 1 | 7.2 | 320 | 350 | 56 |
| Comparative | Glycine | Colloidal | 0.3 | 30 | 2 | 6 | 750 | 450 | 110 |
| Example 1 | | Silica | | | | | | | |

As shown in Table 2, it is found that, when the respective metal-polishing liquids of the examples were used, in comparison with the case where the metal-polishing liquid of the comparative example was used, without largely lowering a copper polishing speed, polished surfaces that were improved with respect to dishing were obtained, and further, the copper/tantalum polishing speed ratio was excellent and the copper/tantalum polishing selectivity was excellent. In particular, according to the comparison between the examples and the comparative example, it is found that when the particular amino-acid derivative and the particular colloidal silica were used, the dishing could be largely improved.

According to the invention, a metal-polishing liquid that has rapid CMP speed and excellent copper/tantalum polishing selectivity and is less in the dishing to be able to improve the planarity of a surface to be polished and a polishing method therewith may be provided.

All publications, patent applications, and technical standards mentioned in this specification are herein incorporated by reference to the same extent as if each individual publication, patent application, or technical standard was specifically and individually indicated to be incorporated by reference.

What is claimed is:

1. A metal-polishing liquid that is used in chemical mechanical polishing for a conductor film made of copper or a copper alloy during semiconductor device production, wherein the metal-polishing liquid comprises the following components (1), (2) and (3):
(1) an amino-acid derivative represented by the following formula (I) 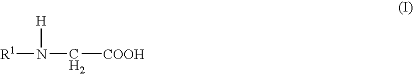
wherein in the formula (I), R¹ represents an alkyl group having 1 to 4 carbon atoms;
(2) colloidal silica in which silicon atoms on a surface thereof are at least partially modified by aluminum atoms; and
(3) an oxidant.

2. The metal-polishing liquid of claim 1, wherein the (1) amino-acid derivative represented by the formula (I) is N-methylglycine or N-ethylglycine.

3. The metal-polishing liquid of claim 1, wherein the (2) colloidal silica in which silicon atoms on a surface thereof are at least partially modified by aluminum atoms has a primary particle diameter in the range of from 20 to 40 nm, and a degree of association thereof is 2 or less.

4. The metal-polishing liquid of claim 1, further comprising a tetrazole or derivative thereof.

5. The metal-polishing liquid of claim 1, wherein the pH thereof is in the range of from 4 to 9.

6. A polishing method comprising chemical mechanical polishing a substrate having a conductor film made of copper or a copper alloy with a metal-polishing liquid that contains the following components (1), (2) and (3) during semiconductor device production:
(1) a compound represented by the following formula (I) 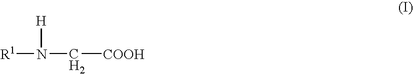
wherein in the formula (I), R¹ represents an alkyl group having 1 to 4 carbon atoms;
(2) colloidal silica in which silicon atoms on a surface thereof are at least partially modified by aluminum atoms; and
(3) an oxidant.

7. The polishing method of claim 6, wherein the polishing comprising polishing a substrate surface with a polishing pad which is attached on a polishing platen by moving the polishing pad and the substrate surface to be polished relatively in a state in which the substrate surface to be polished is pressed by the polishing pad with pressure of 20 kPa or less while the metal-polishing liquid is fed to the polishing pad.
